(19) United States
(12) Patent Application Publication
(10) Pub. No.: US 2002/0015287 A1
(43) Pub. Date: Feb. 7, 2002

(54) Cooling system and method for a high density electronics enclosure

(76) Inventor: Charles Shao, San Marino, CA (US)

Correspondence Address: O'MELVENY & MYERS LLP, 400 So. Hope Street, Los Angeles, CA, 90071-2899, US

(21) Appl. No.: 09/827,101

(22) Filed: Apr. 5, 2001

Related U.S. Application Data
(60) Provisional application No. 60/194,719, filed on Apr. 5, 2000.

(51) Int. Cl. H05K 7/20

(52) U.S. Cl. 361/695

(57) ABSTRACT

An electronics enclosure implementing a cooling system and method enables much higher power densities in air-cooled electronic enclosures. The system includes an air streaming or “tunneling effect” ventilation system, including an enclosure that functions as a heat transfer component of the system, that efficiently removes warm air from the interior of the enclosure. The ventilation system comprises an array of intake fans on a first side panel of the enclosure, an array of exhaust fans on an opposing side panel of the enclosure, and a substantially unobstructed channel between the side panels. Additionally, an external heat exchanger is provided that is integrated with the enclosure for dissipation of heat from high-density powered components such as hard drives. The system further includes a thermoelectric cooling module with a heat exchanger and an optional externally ported CPU fan to achieve superior heat dissipation from the CPU.

### CROSS-REFERENCE TO RELATED APPLICATION

This application claims priority pursuant to 35 U.S.C. § 119(e) to U.S. Provisional Application No. 60/194,719, filed Apr. 5, 2000, which application is specifically incorporated herein, in its entirety, by reference.

### BACKGROUND OF THE INVENTION

1. Field of the Invention

The present invention relates to computer hardware, and more particularly to computer hardware for network server clusters, and cooling systems for electronics enclosures.

2. Description of Related Art

The emergence and growth of Internet usage, along with growth in other forms of telecommunications, have created a greatly increased need for network servers to handle an increasingly immense volume of Internet and other computer network traffic. Often, the task of handling such traffic is most cost-effectively managed by server clusters comprised of a large number of component servers. For example, server clusters comprised of several hundred component servers are not uncommon. The individual servers for use in traffic management clusters are not high-end computers. It is more cost effective to use servers with components of generally the same type as are used in relatively inexpensive personal computers designed for home and general office use. Such components are less expensive than components designed for more computationally intensive, high-end tasks, and yet are capable of handing traffic management tasks with sufficient speed. It is much more cost-effective to provide a large number of such relatively less sophisticated servers to provide the server cluster with sufficient traffic handling capacity, compared with designing and building more sophisticated servers dedicated for traffic management. However, the use of commercially available components places certain constraints on the physical arrangement of the servers and server cluster.

There are significant facility costs associated with maintaining large server clusters. Such servers must be maintained in secure, climate controlled areas with adequate power and back-up power supplies, sometimes referred to as “server farms”. Large server clusters according to the prior art typically require a relatively large amount of space in dedicated server farms, which in turn can lead to substantial costs. For example, operators of server farms often charge server operators based on the size and number of rack slots required by the server operator. Furthermore, as a server cluster grows by the addition of new servers, it can become too large for its original facility, necessitating further costs of facility expansion, relocation, or cluster densification. In addition, facility expansion is often not feasible and can be very expensive, and relocation efforts can create a serious risk of prolonged server failure or downtime. At the same time, a server cluster failure can be very expensive in terms of lost network traffic, inconvenience, and lost opportunity, especially when the traffic from millions of individual users is passing through the cluster.

Cluster densification would avoid these facility costs and risk of downtime, but densification is limited by technological factors, and in particular, by the need to prevent overheating of server components. It has long been recognized that effective cooling of electronics components in computers is critical to maintaining reliable operation. To maintain the reliability of a cluster, the individual servers making up the cluster must be configured for proper dissipation of heat generated by the servers' central processing units (CPU's), power supplies, hard drive motors, and other powered components. However, the cooling capacity of electronic enclosures in prior art rack systems has limited the density of commercially available network server clusters to 41 servers per industry standard 19″41U rack, which is much less than the theoretical density achievable using commercially available, compact computer components. At substantially higher cluster densities, the limitations of prior art cooling systems and methods lead to increased operating temperatures, which can in turn severely impair the reliability and service life of the cluster. Other trends, including trends towards increasing CPU frequency, installed RAM memory capacity, and hard drive capacity or spinning speed, also create additional heat load and place increasing demands on computer cooling systems. At the same time, as the density of the cluster increases, the space available for cooling systems decreases, thereby increasing the difficulty of providing adequate cooling without resorting to more expensive and relatively complex systems, such as liquid refrigeration systems. Prior art cooling systems and methods for rack-mounted electronic enclosures that rely on air exchange with the ambient, “room-temperature” environment have failed to satisfactorily address this conundrum.

Therefore, there exists a need for a cooling system and method for which cost-effectively overcomes the limitations of the prior art, thereby enabling operation of server cluster having much higher physical densities than heretofore permitted.

### SUMMARY OF THE INVENTION

By introducing innovations for heat dissipation and other improvements on the enclosure design for high density components, the present invention makes it possible to achieve server densities that are four or more times higher than server densities achieved in the prior art, by shrinking the volume occupied by each server to one-quarter the size of prior art servers, or smaller. At the same time, a high density server cluster according to the present invention enables reliability, economy, and ease of use that are equal to or better than achieved in prior art server clusters, and can be installed in a conventional rack space and in a conventional server farm environment without requiring specialized cooling equipment.

An electronics enclosure implementing a system and method according to the present invention enables a cool operating environment for each electronics enclosure and each server in the cluster. Radical improvements in heat dissipation methods are combined with a low-power system board to achieve an inherently cool and stable operating environment, with ample capacity for increases in power density. The present invention includes an integrated hard drive heat exchanger with active ventilation for dissipation of heat from high-density mounted hard drives. An innovative thermoelectric cooling module with a heat exchanger and an optional externally ported CPU mounted fan is further provided to achieve superior heat dissipation from the CPU. In addition, an air streaming or “tunneling effect” ventilation system, including an enclosure that functions as a heat transfer component of the system, is provided that removes warm air from the interior of each electronics enclosure much more efficiently than prior art methods.

Each of the foregoing innovative features, especially in combination, enable construction of high density server clusters more easily, and in a much more compact physical space, than previously possible. The innovative cooling systems of the present invention may also be applied to lower-density computer enclosures, and to other types of electronics enclosures wherever improved cooling capacity is required.

A more complete understanding of the innovative cooling system and method, and their application to a high density server cluster will be afforded to those skilled in the art, as well as a realization of additional advantages and objects thereof, by a consideration of the following detailed description of the preferred embodiment. Reference will be made to the appended sheets of drawings which will first be described briefly.

### BRIEF DESCRIPTION OF THE DRAWINGS

FIG. 1 is a perspective view from above a 1/4U electronics enclosure according to the invention.

FIG. 2 is a perspective view of 4U electronics enclosures according to the prior art.

FIG. 3 is a perspective view from below a 1/4U electronics enclosure according to the invention, showing a heat exchanger coupled to the bottom panel of the enclosure.

FIG. 4 is a cutaway view of an electronics enclosure according to the invention, showing the position of the internal server components on the platform.

FIG. 5 is a partial cross-sectional view showing a detail of the heat exchanger shown in FIG. 3.

FIG. 6 is a cross-sectional view of an electronics enclosure, showing intake and exhaust fans and a pressurized and directional ventilation channel over the server motherboards.

FIG. 7 is a perspective cutaway view of an enclosure for a server platform with arrows showing operation of ventilation system for dissipating heat from the system boards mounted inside the server platform.

FIG. 8 is a cross-sectional view showing a detail of an exemplary fan mounting configuration in a side panel of the electronics enclosure.

FIG. 9 is a front view of the ventilation fan shown in FIG. 8, viewed from the interior of the enclosure.

FIG. 10 is a cross-sectional view showing a detail of an exemplary alternative fan mounting configuration in a side panel of the electronics enclosure.

FIG. 11 is an end view of a an enclosure for a server platform, showing a front panel with an improved design for RJ45 Ethernet connections and an improved KVM switch placement.

FIG. 12 is a side view of an exemplary assembly for cooling an enclosed, powered semiconductor device, such as a server microprocessor enclosed within a 1/4U enclosure.

FIG. 13 is a side view of an exemplary assembly for cooling an enclosed, powered semiconductor device, such as a server microprocessor enclosed within a 1/4U enclosure, according to an alternative embodiment of the invention.

### DETAILED DESCRIPTION OF THE PREFERRED EMBODIMENT

The present invention satisfies the critical need for an economical and more powerful cooling system and method for a high-density server cluster. In the detailed description that follows, like element numerals are used to describe like elements shown in one or more of the figures.

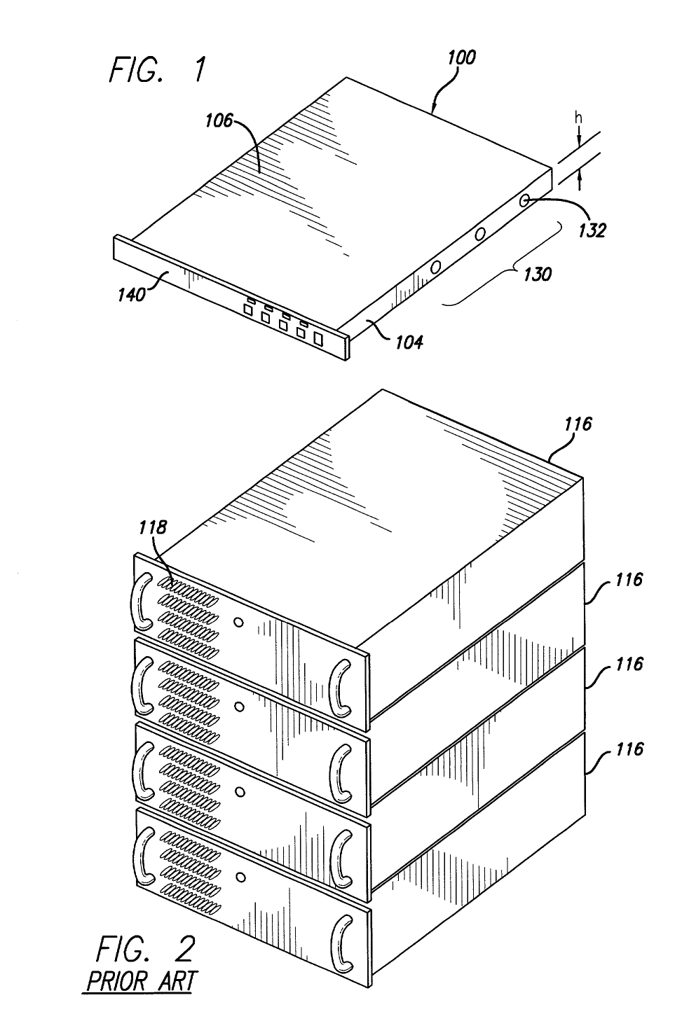

Referring to FIG. 1, an electronics enclosure 100 according to the present invention preferably comprises a rectilinear box configured to fit an industry standard 41U rack. More preferably, the electronics enclosure 100 is configured to occupy a single standard 1.75 inch high bay of a standard 41U rack, and to house four or more servers. That is, the height “h” of enclosure 100 is nominally 1.75 inches, the width of the enclosure is nominally 19 inches, and the depth of the enclosure is nominally 28 inches. Of course, the electronics enclosure 100 may be configured to fit other types of racks or to occupy more than one bay of a rack, or as a free-standing enclosure, without departing from the scope of the invention.

Exemplary space reduction provided by an enclosure according to the present invention is apparent from comparison of FIGS. 1 and 2. FIG. 2 shows exemplary 4U enclosures 116 according to the prior art, each configured to house a single server. Thus, the four prior art enclosures 116 occupy approximately sixteen times more rack volume than enclosure 100, while housing the same number of servers. Ventilation ports 118 are evident on the front panels of the 4U enclosures 116, as is typical of the prior art.

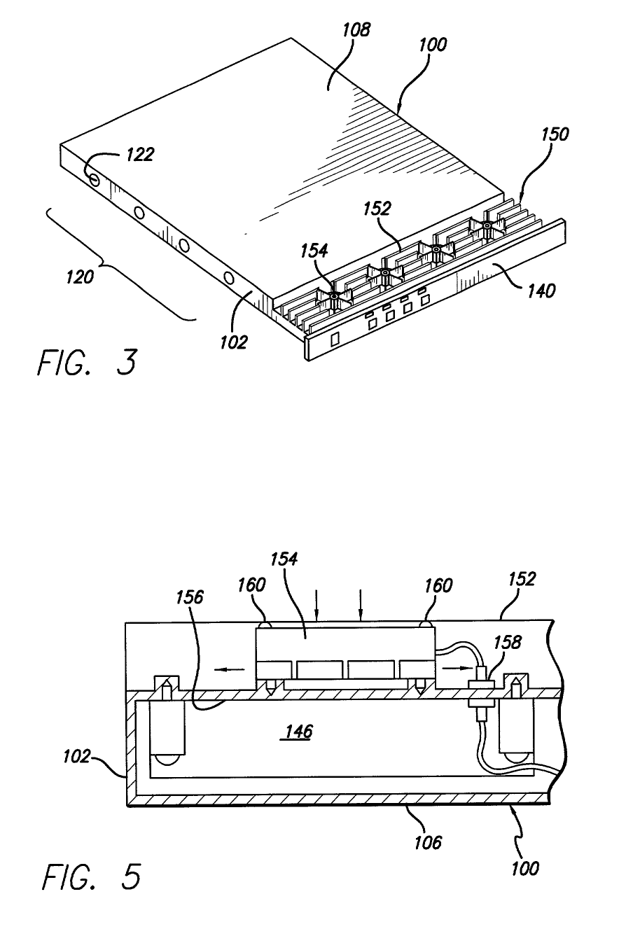

Referring to FIGS. 1 and 3, enclosure 100 comprises six panels: top panel 106, bottom panel 108, front panel 140, a first side panel 102, a second side panel 104, and a back panel (not shown). An intake fan array is preferably located in side panel 102, of which intake ports 122 are shown in FIG. 3. An exhaust fan array is preferably located in the second, opposing side panel 104, of which exhaust ports 132 are shown in FIG. 1. The number of exhaust ports 132 may be less than the number of intake ports 122 (as shown), or in the alternative, the same number, or a greater number, of exhaust ports may be provided. However, a lesser number of exhaust ports may be particularly useful for an embodiment of the invention wherein an exhaust flow rate is less than an intake flow rote, as described in more detail later in the specification.

The panels of enclosure 100 are preferably comprised of a superior heat-conducting material, such as an aluminum alloy. Prior art rack-mounted enclosures are typically comprised of a steel alloy (i.e., a sheet metal steel cover assembled to a stamped steel frame). However, steel is a relatively poor heat conductor, and is relatively heavy. Aluminum alloys are preferred, because of their relatively high thermal conductivity, strength, light weight, and relatively low cost. Aluminum panels of enclosure 100 may be optionally be surface treated to protect the aluminum from corrosion, to increase its heat emissive characteristics, and/or to achieve a desired cosmetic effect. Painting or anodizing, which may diminish the thermal conductivity of the aluminum, are generally not preferred. Details of the assembly of enclosure 100 may conform to various conventional methods. For example, the panels may comprise separate pieces that are assembled to a frame (not shown), may be formed by bending a single piece of sheet aluminum, or may comprise a combination of separate and unitary pieces.

As shown in FIG. 3, enclosure 100 is optionally provided with a heat exchanger 150 in bottom panel 108. In the alternative, or in addition, a similar heat exchanger (not shown) may be provided in top panel 106. Heat exchanger 150 comprises an array of vertically oriented fins 152 conductively coupled to an interior surface of enclosure 100. Exchanger 150 optionally includes at least one blower 154 (four blowers shown) for forcing ambient air over fins 152. Exchanger 150 may comprise a separate piece or assembly that is attached to enclosure 100, or may be formed out of an integral piece with bottom panel 108. Further details of heat exchanger 150 are provided below in connection with FIG. 5.

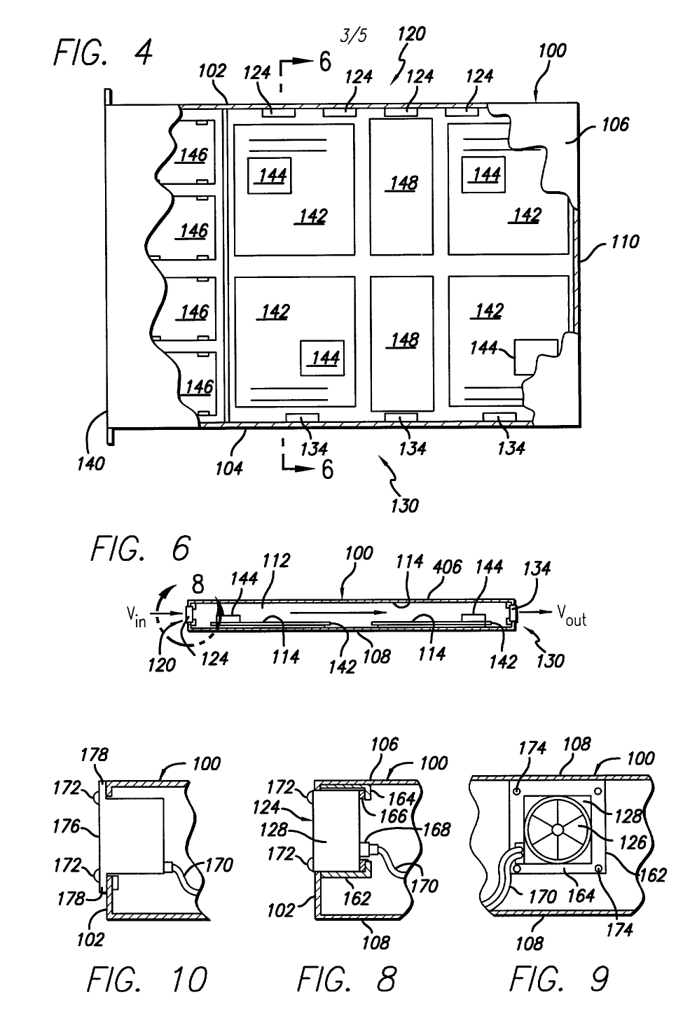

Referring to FIG. 4, system boards 142 each having a CPU 144 are preferably mounted in electronics enclosure 100, such as by mounting to stand-offs fastened to a frame, or by another conventional method. Power supplies 148 are preferably mounted adjacent to system boards 142 where indicated in FIG. 4. In an alternative embodiment, the power supplies are removed from the electronics enclosure 100 and mounted in a remote location (not shown). Hard drives 146 are preferably mounted in the enclosure with a mounting surface in conducting contact with an integrated heat exchanger 150 (an exemplary one hard drives 146 is shown in FIG. 3). Intake fan assemblies 124 are provided adjacent to first side panel 102, comprising an intake fan array. Exhaust fan assemblies 134 are provided on the opposing second side panel 104, comprising an exhaust fan array. Components on electronics enclosure 100, including system boards 142, hard drives 146 and power supplies 148 are preferably substantially enclosed within the interior of electronics enclosure 100 by sides 102 and 104, top 106, bottom 108, back panel 110, and front panel 140.

Mounting multiple system boards 142, power supplies 148, and hard drives 146 in a single electronics enclosure 100 will create an unacceptable build-up of heat in the electronics enclosure 100 unless special measures are taken. The present invention provides several improvements and innovations to the design of the electronics enclosure 100 and its internal components to provide for the necessary cooling. These innovations and improvements are described in greater detail below.

### Exterior Heat Exchanger

Hard drives are a significant source of heat within electronics enclosure 100, particularly because of the high spin rates and closely packed spacing of the preferred high performance drives. Furthermore, the preferred low profile (such as about 1.75 inches) of enclosure 100 leaves little room available inside the enclosure for convective cooling of hard drive components, which are typically considerably thicker than most other components within the enclosure, such as system boards and semiconductor devices. Therefore, in an embodiment of the invention, hard drives 146 are preferably mounted with a mounting surface 156 in conductive contact with heat exchanger 150 on the exterior of the enclosure, as shown in FIG. 5. Conduction of heat from surface 156 to the heat exchanger 156 may be enhanced by interposing a heat transfer paste (not shown), or other suitably compliant and heat-conductive material as known in the art, between mounting surface 156 and heat exchanger 150. Heat may therefore be efficiently transferred by conduction from the hard drives into the heat exchanger 150 and into fins 152, from whence it is removed by convection to the ambient environment, thereby cooling drives 146 and enclosure 100. It should be apparent that such a cooling arrangement is not limited to use with hard drives, but may be used for similarly configured components of different types.

Heat exchanger 150 is preferably made from a single piece of thermally conductive material, such as aluminum, copper, or brass, and is preferably in direct contact (except for any interposing heat transfer material) with the hard drives. In the alternative, but less preferably, the heat exchanger is mounted in conductive contact with a panel of the enclosure, such as top panel 108, which is in turn conductively coupled to the hard drives. It is generally preferred, however, to avoid interposing extraneous materials between the hard drives and the heat exchanger, as extraneous materials may reduce heat conduction to exchanger 150.

In an embodiment of the invention shown in FIGS. 3 and 5, heat exchanger 150 comprises an array of vertical fins 152 on the exterior of the enclosure 100 for improving convection of heat from the exchanger. The fins may operate by passive convection, or in the alternative, at least one blower 154 may be positioned so as to blow ambient air over fins 152 (such as generally in the direction of the arrows shown in FIG. 5). If necessary, one or more blowers 154 can greatly reduce the operating temperature of the hard drives 146 by removing heat more quickly from heat exchanger 150 by forced convection.

Blowers 154 are preferably configured to be readily removable and replaceable from the exterior of enclosure 100. A suitable configuration is shown in FIG. 5. Blower 154 is mounted directly to a surface of heat exchanger 150 or enclosure 100 by fasteners 160 on the outside of enclosure 100, and is connected through a feed-through socket to power and optionally control signals provided from the electronics within the enclosure. Fasteners 160 may readily be removed from outside of enclosure 100, and the blower may be disconnected at feed-through socket 158.

In addition to or instead of fins 152, heat exchanger 150 may comprise a high emissivity coating on the exterior of heat exchanger 150, or at least one channel (not shown) to direct exhaust air from the interior of enclosure 100 over the heat exchanger, either before or after exhausting the air to the exterior of the enclosure. Heat exchanger 150 may additionally, or in the alternative, rely on an external blower such as a rack fan for forced movement of cooling air over its heat transfer surfaces. Each of these alternative embodiments advantageously improves convection from heat exchanger 150, without requiring a dedicated blower 154.

### Tunnelling Ventilation System

Other interior components, such as CPU's 144, power supplies 148 and system boards 142, also generate substantial heat inside the electronics enclosure 100. Because of the high density of the server configuration in the present invention, prior art methods of ventilating the interior of the electronics enclosure 100 to remove this heat are no longer adequate. The present invention provides the cooling capacity required for higher-density and higher temperature components using an innovative ventilation system and method comprising opposing arrays of intake and exhaust fans. The present method cools more efficiently than prior art methods, by efficiently removing warm air from the electronics enclosure using a “tunneling” forced-air convection design that eliminates stagnant air, and removes heat more effectively to the exterior of the server casing.

Referring again to FIG. 4, an intake array of fans 120, comprising a row of intake fan assemblies 124, is preferably provided along a first side 102 of electronics enclosure 100, and configured to blow ambient air into enclosure 100. A corresponding exhaust fan array 130, comprising of exhaust fan assemblies 134 along a second side panel 104 opposite the first side panel 102, is configured to exhaust ambient air from the enclosure. Intake fan array 120 is preferably positioned in alignment with exhaust fan array 130. In an embodiment of the invention, at least one array of the intake and exhaust arrays extends across a side panel for substantially all of the width of the system boards 142 within enclosure 100.

Fan arrays 120 and 130 are preferably comprised of commercially available fans for ventilation of electronics enclosures. Such fans may be reversible, depending, for example, on the polarity of the voltage applied to them, but are preferably configured to blow air in a single direction. That is, the fans 124 in the intake array 120 preferably always serve as intake fans, and the fans 134 in the exhaust array preferably always serve as exhaust fans. The flow capacity of the fans may depend on the voltage of power supplied, may be substantially constant over a range of voltages, or may be controlled by a control signal. Preferably, the fans are configured to run at less than full capacity, such as about 50% of full capacity, under normal operating conditions. If internal temperatures exceed preset limits, such as in response to additional heat load from internal components or higher ambient temperatures, the fan speed may then be increased to provide adequate cooling capacity. It should be apparent that the invention is not limited to the use of motorized fans as air movement devices, and other suitable devices, such as, for example, remotely located air compressors or static charge devices, may be used instead of fans without departing from the scope of the invention.

Preferably, at least two intake fans 124 are provided in the intake array 120, and are uniformly spaced in side panel 102 across system boards 142. Similarly, at least two exhaust fans 134 are preferably provided in the exhaust array 130 uniformly spaced in side panel 104 across system boards 142. In an embodiment of the invention, slightly fewer exhaust fans are provided than intake fans. For example, as shown in FIG. 4, four intake fans and three exhaust fans may be provided. The number and arrangement of fans depends on the geometry and air flow requirements of the enclosure to be cooled thereby. Preferably, the fans and arrays should be configured to draw a sufficient volume of air in a fairly uniform air stream running across the enclosure between opposing side panels. Accordingly, the number and arrangement of fans in the fan arrays may vary from the embodiments shown and described herein, without departing from the scope of the invention.

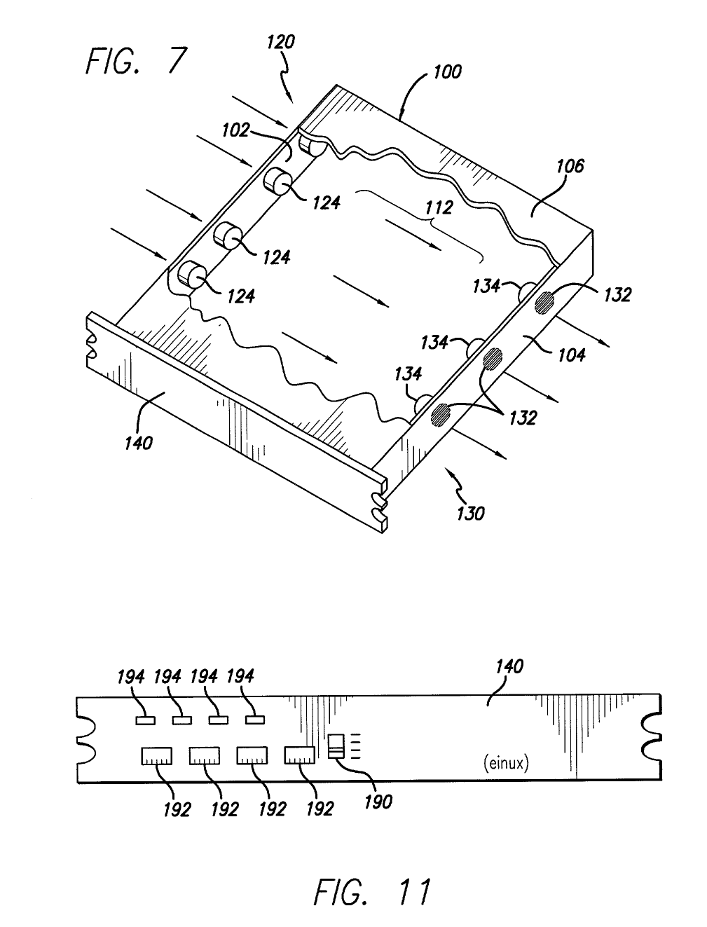

A preferred mode of operation of the ventilation system is shown in FIGS. 6 and 7. In the preferred mode of operation, intake fan array 120 draws cooling air from the exterior, and drives it into the interior of electronics enclosure 100 at an intake mass flow rate “Vᵢₙ”. Exhaust fan array 130 draws warm air from the interior of enclosure 100, and exhausts it to the exterior of side panel 104 at an exhaust mass flow rate “Vₒᵤₜ” that is slightly less than Vᵢₙ. Within the interior of enclosure 100, a substantially unobstructed channel 112 provides a conduit for movement of air between the intake array 120 and the exhaust array 130. Preferably, the ventilation system is configured so that a ventilation ratio “VR,” defined as the ratio of the exhaust rate to the intake rate (Vₒᵤₜ/Vᵢₙ), is set to a maximum value, such as, for example, about 0.50 to 1.0, and more preferably, about 0.90 to 0.99, whereby the interior of enclosure 100 is pressurized to slightly above ambient pressure. It should be apparent that if VR is greater than unity, the enclosure 100 will be suctioned to a negative (less than ambient) pressure. A negative pressure within enclosure 100 is not preferred; however, the system is capable of operating at negative pressure. The intake rate Vᵢₙ preferably is determined by the heat load within the enclosure and the anticipated ambient temperature, and the exhaust rate is adjusted to maintain VR within a desired range.

When the ventilation system is configured and operated according to the preferred mode described above, a surprisingly efficient cooling effect is observed, herein referred to as “tunneling.” It has been demonstrated that, surprisingly, the tunneling effect provides for dramatically greater cooling than operating the fan arrays in an open enclosure (such as with top panel 106 removed) or in a suction mode (VR>1). In tunneling mode, cooling air moves rapidly through the interior of electronics enclosure 100 and is exhausted quickly through exhaust array 130, as indicated by the flow arrows in FIGS. 6 and 7. The intake and exhaust rates are preferably controlled so that a stream of air flows through a channel 112 in the interior of the enclosure at an average rate not less than the exhaust rate. Also, the dwell time of air inside the electronics enclosure is less in tunneling mode than with prior art methods. Because of the reduced dwell time, the air is exhausted at a lower temperature, which reduces the interior temperature of the electronics enclosure 100 and its interior components compared to prior art methods. At the same time, the air velocity inside the platform is increased, and substantially all of the hot interior components are exposed to the cooling air stream, both factors which greatly enhance convective heat transfer from the interior components. As an incidental benefit, pressurizing the enclosure 100 prevents infiltration of particulate matter into the enclosure, because all of the intake air passes through the fan assemblies 124 in the intake array 120, which may be provided with suitable filtration as known in the art. Furthermore, rapid movement of air inside the enclosure tends to prevent particulate matter from settling out, so that any particles that pass through the intake filters are exhausted instead of attaching to interior components.

The performance capabilities of the tunneling ventilation system have been confirmed in laboratory tests. For example, in a test of an enclosure having nine intake fans and four exhaust fans (all of the fans having a capacity of about 10 CFM), an air temperature increase inside of the enclosure adjacent to the microprocessors of about four degrees was observed. In comparison, in a test of a similarly-sized enclosure equipped with a prior art ventilation system under the same loading conditions, a temperature increase of greater than twenty degrees was observed. Furthermore, the tunneling ventilation system achieved approximately the same temperature increase (about four degrees Celsius) over a wide range of ambient temperatures. Such results indicate that a tunneling ventilation system may be configured to provide adequate system cooling over a wider range of ambient temperatures, and thus may provide a more fail-safe system.

The intake rate of the intake fan array, and the exhaust rate of the exhaust fan array, may be actively controlled, for example, by varying the voltage supplied to the fans in the array depending on a measured factor such as the interior air temperature or pressure. For example, the intake rate may be controlled to maintain an interior air pressure in the enclosure that is greater than ambient pressure. Alternatively, selected fans in the fan arrays may be switched on or off depending on a measured factor. For some applications, operating conditions may be relatively constant and fairly uniform across different installations. For such applications, the intake and exhaust flow rates may be substantially fixed during operation.

Less preferably, in alternative modes of operation, fan array 130 is omitted, leaving only the array of ports 132 in the second side panel 104. Fan array 120 blows air into the enclosure, thereby pressurizing the enclosure. Warm air is exhausted through ports 132. In the alternative, fan array 120 is operated in reverse to exhaust warm air from the interior of electronics enclosure to the exterior of the platform, creating suction in the interior of the case. Thus, cool air is drawn inside the electronics enclosure 100 through ports 132. The single array of fans 120 with an opposing array of ports 132 provides better cooling than prior art methods. As compared to operating a single fan array in an exhaust mode, a greater cooling effect is observed when operating fan array 120 in an intake mode whereby the enclosure is pressurized. However, in both intake and exhaust modes, the tunneling effect is greatly diminished between the fan array 120 and the array of ports 132. Therefore, the cooling capacity is less than can be achieved using dual fan arrays 120, 130 operating in tunneling mode.

As shown in FIG. 6, a substantially unobstructed channel 112 spans across enclosure 100 from the intake fan array 120 to the exhaust fan array 130. A perspective view of channel 112 is shown in FIG. 7. Channel 112 is defined by opposing parallel walls 114 which are principally comprised of the top panel 106 and the system boards 142. Thus, the system boards comprise at least a portion of a sidewall 114 of channel 112, and are directly exposed to the air stream indicated by the flow arrows. More than one channel 112 may optionally be provided; for example, the system boards 142 may be positioned so that air flows along both surfaces (upper and lower) of each system board, effectively dividing the space between the top panel and the bottom panel into two parallel channels. At least one of the top panel 106 or the bottom panel 108 also comprises at least a portion of a sidewall 114 of channel 112, and is also exposed to the air stream and to the exterior of enclosure 100. Accordingly, top panel 106 and/or bottom panel 108 are optionally configured as heat transfer components, such as by constructing the panels from a conductive material, or providing features on their interior or exterior surfaces for enhancing convective or radiative heat transfer to the ambient environment. For example, the panels 106, 108 may be made of aluminum that is surface treated to increase emissivity on its interior and exterior surface, and/or provided with fins (not shown) for convective heat transfer on its exterior surface and/or interior surface.

Although certain components, such as CPU's 144, may protrude from the boards 142 into the channel 122, the overall effect of such protrusions is preferably such that the flow area across the width of channel 112 is substantially unobstructed. One skilled in the art will recognize that the extent to which channel 112 may be partially occluded will depend on a variety of factors, including the shape and location of the obstructions, the desired air flow rate, and the amount of unobstructed flow area which remains in channel 112. As a general rule of thumb applicable to 1/4U server applications, however, it is preferable to space the walls 114 between about 0.5 and 1.75 inches apart, with substantial obstructions into the channel limited to less than about 25% of the channel width in the direction of side panels 102, 104.

Details of an exemplary intake fan 124 mounted in side panel 102 are shown in FIGS. 8 and 9. A side cross-sectional view is shown in FIG. 8, with the fan 124 shown in full. A front view looking from the interior of enclosure towards the rotor 126 of fan 124 is shown in FIG. 9. Fan 124 is preferably a commercially available axial fan having a height approximately equal to the height of channel 112. Such fans are commonly available in compact sizes for electronics applications, such as with rotors between about 0.5 to 1.5 inches in diameter, which is within a useful size range for mounting in the side panels of 1/4U enclosures.

Fan 124 is typically available as a pre-assembled module within a mountable fan casing 128. A fan mounting socket 162 is provided in side panel 102. Fan casing 128 fits inside socket 162 and against mounting flange 164 with rotor 126 facing the interior of enclosure 100 and positioned to blow air along channel 112. An optional gasket 166 comprised of a soft elastic or compliant material is interposed between fan casing 128 and flange 164, and around the perimeter of the casing. A gasket, such as gasket 166, may be used for sealing the enclosure and/or reducing noise and vibration caused by the fan. Fan 124 may be held in place by threaded fasteners 172 which attach to threaded holes 174 in flange 164. Power cable 170 runs to the interior of enclosure 100, and is removably attached to casing 128 at connector 168. Fan 124 is thus preferably configured for removal and replacement without opening enclosure 100. Equivalent fans and mounting configurations may be used for exhaust array 130.

FIG. 10 shows an alternative configuration for mounting a fan, using a fan casing 176 having an integral flange 176 that is fastened directly to side panel 102. It should be appreciated that various other alternative types and configurations of fans or other forced air movement devices may be employed in fan arrays 120, 130 without departing from the scope of the invention. It should further be apparent that the intake and exhaust arrays may be provided on any two opposing side panels, such as, for example, front panel 140 and back panel 110, so long as a substantially unobstructed channel may be configured between the opposing panels as described herein. Disposing the intake and exhaust arrays in side panels 102 and 104 is preferable for rack-mounted enclosures having interior components configured as shown, for example, in FIG. 4. However, the invention is not limited to such embodiments.

### EXAMPLE ONE

The enhanced cooling capacity of the ventilation system according to the present invention is illustrated by the following example: An enclosure is provided with an intake fan array comprised of eight 40 mm×10 mm fans in one side panel. Each of the fans operates at a flow rate of 11.3 cubic feet per minute (“CFM”). The flow capacity of the array is therefore about 90 CFM, which corresponds to a mass flow rate of about 0.11 lbm/sec at 80° F. The enclosure is well-sealed, and the exhaust rate through the exhaust array is set to slightly less than the intake rate through the intake array, such as a VR of about 0.99. Therefore, the pressure increase across the intake array is small, and the fans in the array will operate at close to their maximum flow rate. The average flow rate through the enclosure and the exhaust rate will thus both be about 90 CFM. The substantially unobstructed channel between the opposing side panels is about 17 inches long, having an average cross-sectional area of about 30 square inches, typical for a single-bay, 41U rack enclosure. Accordingly, the average air speed in the channel will be about 7.3 feet/second and the average dwell time of air within the chamber about 0.2 second, or about five changes per second.

The theoretical cooling capacity of the exemplary system may be determined by the flow rate multiplied by the heat capacity of air, giving for the exemplary system a theoretical capacity of about 40 Watts/° C. A single server dissipates about 120 watts, and therefore each server within the case can contribute to increase in the exhaust air temperature of at most three degrees Celsius, assuming all of the heat load is transferred to the air stream. In a four-server, 480 watt enclosure equipped with the exemplary ventilation system, the maximum exhaust increase will thus be twelve degrees. However, in the typical case, a portion of the heat load will be dissipated through some other pathway, such directly through the enclosure walls. Accordingly, the actual temperature increase will be lower. Advantageously, because of the frequent air changes and absence of stagnant pockets of air within the enclosure, the internal air temperature increase will be less than the theoretical maximum exhaust temperature increase of about twelve degrees.

The low internal air temperature in conjunction with the rapid air velocity will help achieve optimum heat transfer from the electronic components exposed to the air flow. Calculation of the heat transfer is complex, and will vary depending on the configuration and placement of components within the enclosure. However, it should be appreciated that the electronic components in the enclosure will be maintained at relatively low temperatures compared to prior art systems with higher internal air temperatures and lower flow rates. It should further be appreciated that at the exemplary flow conditions described above, the flow of air will be turbulent. Turbulent flow is generally preferred over laminar flow, because greater heat transfer rates from the electronic components to the air stream may be achieved under turbulent flow conditions.

### EXAMPLE TWO

An aluminum 1U enclosure was equipped with nine intake fans and four exhaust fans in opposing side panels. Each of the fans measured 40 mm square by 10 mm thick, at the fan casing, and had a maximum flow capacity of 11.3 CFM. A single server, comprising a 1 GHz Athlon™ processor from AMD™, 1 GB of ECC memory, a 30 GB 5200 rpm hard drive, and associated components, was installed in the enclosure. The fans and the internal components were powered on, with the fans operated at full speed. The imbalance in the fan arrays created a positive pressure inside the enclosure. The ambient temperature was set and controlled using a climate control system. The intake (ambient) temperature (“T₁”) and internal air temperature at between 0.5 and 1.0 inch away from the CPU (“T₂”), were measured at steady state, for various different ambient temperatures. Results are reported in Table 1, with ΔT equal to the difference between T₁ and T₂.

The same server components were installed in an aluminum 1U enclosure equipped with four intake fans and eight exhaust fans of the same type as described above. The fans were operated at full speed, thereby creating negative pressure within the enclosure. Temperatures were measured as before, and results are reported in Table 2. Comparison of the results reported in Tables 1 and 2 shows that the substantially lower internal temperatures were achieved by the positive pressure configuration.

TABLE 1

| T₁ (° C.) | T₂ (° C.) | ΔT (° C.) |
|---|---|---|
| 30.0 | 34.0 | 4.0 |
| 33.3 | 37.4 | 4.1 |
| 36.1 | 40.1 | 4.0 |
| 38.0 | 42.3 | 4.3 |

TABLE 2

| T₁ (° C.) | T₂ (° C.) | ΔT (° C.) |
|---|---|---|
| 32.0 | 46.0 | 14.0 |
| 34.0 | 47.0 | 13.0 |
| 37.9 | 52.2 | 14.3 |

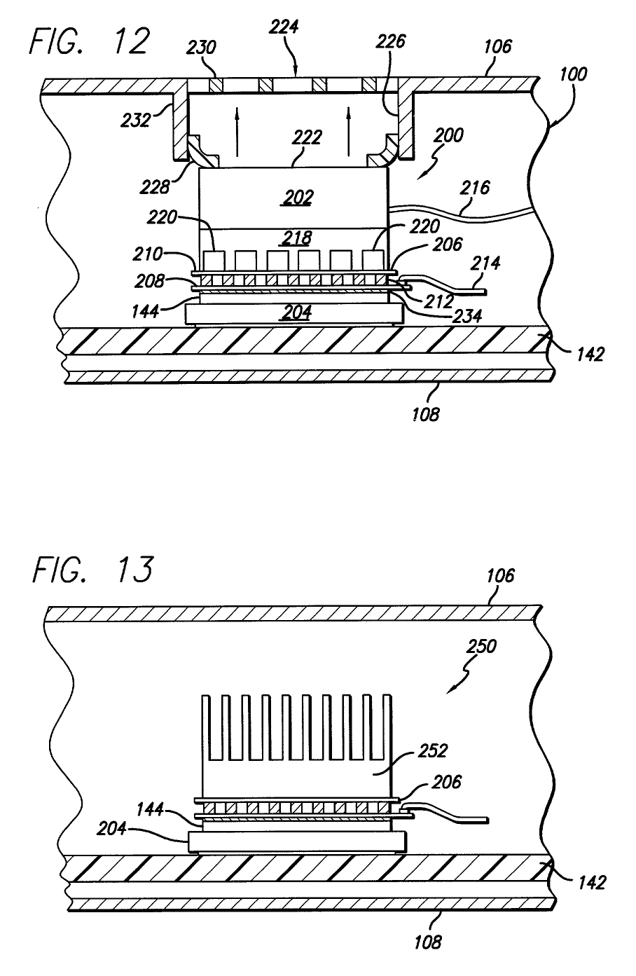

The present invention provides for a high-density server cluster; in other words, for more servers occupying less space. In addition to the cooling problem described above, another problem that becomes more important with increasing server density is cabling and control of the individual servers in a tight space. Thus, the invention preferably provides an improved front panel 140 for electronics enclosure 100. Referring to FIG. 11, front panel 140 incorporates one or more connector sockets 192, which are typically RJ45 Ethernet connections, although other connections may be provided. Front panel 140 also preferably includes a plurality of LED's 194 which indicate various operational states of the servers mounted inside electronics enclosure 100. In addition, a digital KVM (Keyboard-Video-Monitor) switch 190 is preferably provided on front panel 140, providing for convenient push-button connection of a keyboard and video monitor to any server located inside electronics enclosure 100.

### CPU Cooling System

The CPU is another heat source for which the invention provides an efficient cooling system. It is especially important to prevent heat build-up in the CPU because the CPU generally is the electronic component with the highest power inside of the enclosure, and excessive temperatures in the CPU can be a direct cause of server failures. In addition, the CPU is typically the most expensive and most critical single component in a server. Referring to FIG. 12, the present invention provides an innovative assembly 200 for cooling CPU 144, which is mounted to system board 142 by socket 204. Assembly 200 is not limited to use for cooling a CPU, and may be used to cool any suitable powered semiconductor device having a free surface for mounting to the assembly.

Thermoelectric module 206, comprising a thermoelectric material 212 interposed between a cool conduction plate 208 and a hot conduction plate 210, is preferably adhered to the free upper surface 234 of CPU 144, using a commercially available conductive adhesive. However, fasteners or clips anchored to socket 56 or board 142 may be used in lieu of, or in addition to, an adhesive material. The thermoelectric material 212 typically comprises a doped bismuth telluride alloy as known in the art, but any suitable thermoelectric material may be used. When a DC voltage is applied to thermoelectric module 206 through leads 214, the temperature of cool plate 208 drops while the temperature of hot plate 210 rises. Heat transferred from CPU 144 to cool plate 208 is “pumped” by the thermoelectric material to the hot plate, where it is removed by heat exchanger 218 and fan 202. The CPU is thereby maintained at a relatively cool temperature while its heat is dissipated to the environment from the relatively hot heat exchanger 218.

Heat exchanger 218 is preferably coupled to the top surface of thermoelectric module 206 using a heat transfer compound such as are commonly available. CPU fan 202 is preferably selected from a variety of commonly available DC motor-driven fans for CPU cooling, which are often available assembled to a suitably configured heat exchanger. In the alternative, thermoelectric module 206 may be omitted, and heat exchanger 218 may be adhered directly to the top surface of CPU 144.

Fan 202 is preferably configured to draw air in through side ports 220 of heat exchanger 218 and out upper port 222. In the alternative, the fan may be configured to draw air in through upper port 222 and drive it out side ports 220. However, this latter mode is less preferred because waste heat is exhausted inside of the enclosure, thereby adding to the heat load inside the enclosure.

A ventilation chimney 226 is preferably provided through the upper surface 106 of electronics enclosure 100, positioned directly over the top of fan 202. Chimney 226 comprises an enclosed channel around the perimeter of an opening 224 in top panel 106. In a first configuration, air is drawn in through side ports 220 and exhausted to the exterior of electronics enclosure 100 through chimney 226 and opening 224 in top panel 106. In a second configuration, by reversing direction of operation of fan 202, chimney 226 provides a channel from opening 224 for cool external air to be drawn into fan 202. Chimney 226 is preferably provided with an EMI screen 230 disposed across opening 224 to electro-magnetically isolate the CPU 144 and other electronic components of the system from the environment. A flexible sealing gasket 228 is optionally disposed between an upper surface of fan 202 and chimney walls 232, to reduce unwanted air leakage of warm air into enclosure 100. By exhausting waste heat from the CPU directly to the exterior of the enclosure using assembly 200, the need for supplemental cooling systems may be reduced.

Enclosures equipped with a tunneling ventilation system may take advantage of the rapid velocity of cooling air within the enclosure to eliminate the need for a dedicated CPU fan such as fan 202. CPU fans comprise rapidly moving parts and therefore are subject to occasional unpredictable breakdowns. When a breakdown of a CPU fan occurs, the CPU may rapidly overheat and fail without warning. Also, to replace a broken fan, the enclosure 100 may have to be opened, which may in turn entail removing the entire enclosure from a rack. It is desirable, therefore, to avoid the use of a CPU fan, but this has proven difficult to accomplish in prior art systems which depend on the use of relatively high-power CPU's, such as general purpose CPU's which are now prevalent for use in computers.

An exemplary CPU cooling assembly 250 for use with a tunneling ventilation system is shown in FIG. 13. Assembly 250 comprises a passive heat exchanger 252 having a plurality of fins 254. Fins 254 are preferably aligned with the direction of tunneling air flow within the enclosure, for maximum air velocity between and over the fins. Heat exchanger 252 is a conventional metallic finned heat exchanger that may be mounted directly to CPU 144. However, even with a tunneling ventilation system the velocity of air flow over fins 254 will be generally less than can be achieved by mounting a CPU fan directly adjacent to the fins, such as in assembly 200. It may be especially advantageous, therefore, to provide assembly 250 with a thermoelectric module 206 as described in connection with FIG. 12 interposed between heat exchanger 252 and CPU 144, for increased cooling effect. Thus, the need for a CPU fan mounted inside the enclosure may be advantageously avoided.

Having thus described a preferred embodiment of the cooling system and method for a high density electronics enclosure, it should be apparent to those skilled in the art that certain advantages of the within system have been achieved. It should also be appreciated that various modifications, adaptations, and alternative embodiments thereof may be made within the scope and spirit of the present invention. For example, an enclosure for a rack-mounted high-density server has been illustrated, but it should be apparent that the inventive concepts described above would be equally applicable to other rack-mounted components and similar enclosures. The invention is further defined by the following claims.

What is claimed is:

1. An electronics enclosure assembly comprising:
an enclosure comprising a first side panel, a second side panel opposite said first side panel, a top panel, a bottom panel, a front panel, a back panel, and a substantially unobstructed channel between said first side panel and said second side panel;
an intake fan array disposed on said first side panel, said intake fan array configured to blow air into said enclosure at an intake rate; and
an exhaust fan array disposed on said second side panel substantially opposite said intake fan array, said exhaust fan array configured to exhaust air from said enclosure at an exhaust rate.

2. The electronics enclosure assembly of claim 1, further comprising means for controlling said intake rate and said exhaust rate.

3. The electronics enclosure assembly of claim 1, further comprising at least one electronics device mounted inside said enclosure between said intake fan array and said exhaust fan array.

4. The electronics enclosure assembly of claim 1, wherein said at least one electronics device further comprises a plurality of system boards, and each of said plurality of system boards comprises at least one CPU.

5. The electronics enclosure assembly of claim 4, wherein each of said plurality of system boards has at least one side comprising at least a portion of a sidewall of said substantially unobstructed channel.

6. The electronics enclosure assembly of claim 4, further comprising a heat exchanger mounted to said at least one CPU, wherein said heat exchanger is disposed in said substantially unobstructed channel.

7. The electronics enclosure assembly of claim 1, wherein at least one of said top panel and said bottom panel comprises at least a portion of a sidewall of said substantially unobstructed channel.

8. The electronics enclosure assembly of claim 1, further comprising a KVM switch on said front panel for making a selectable connection to each of said plurality of system boards.

9. The electronics enclosure assembly of claim 1, wherein said enclosure is configured to fit in one bay of a 41U cabinet rack.

10. The electronics enclosure assembly of claim 1, wherein said exhaust fan array comprises fewer fans than said intake fan array.

11. The electronics enclosure assembly of claim 1, wherein said exhaust fan array comprises a plurality of exhaust fans having an exhaust capacity less than an intake capacity of a plurality of intake fans comprising said intake fan array.

12. A method for cooling an electronics enclosure comprising a first side panel, a second side panel opposite the first side panel, and a substantially unobstructed channel between the first side panel and the second side panel, means for intake of air along the first side panel, the means for intake of air configured to blow air into the enclosure at an intake rate, and means for exhausting air along the second side panel substantially opposite the first side panel, the means for exhausting air configured to exhaust air from the enclosure at an exhaust rate, said method comprising the steps of:
continuously blowing air into the electronics enclosure at the intake rate using the means for intake of air;
simultaneously exhausting air from the electronics enclosure at the exhaust rate using the means for exhausting air; and
controlling the intake rate and the exhaust rate to maintain the interior of the enclosure at an interior pressure.

13. The method of claim 12, wherein said controlling step further comprises controlling the intake rate and the exhaust rate to maintain a stream of air flow through the substantially unobstructed channel at an average rate not less than the exhaust rate.

14. The method of claim 12, wherein said controlling step further comprises controlling the intake rate and the exhaust rate to maintain the interior of the enclosure at an interior pressure greater than an ambient pressure outside of the enclosure.

15. An assembly for cooling a powered semiconductor device enclosed within an enclosure, said assembly comprising:
an enclosure;
a powered semiconductor device mounted in an interior of said enclosure, said device having a free surface opposing an exterior wall of said enclosure;
an opening aligned opposite said free surface in said exterior wall; and
a fan mounted to said assembly and disposed to move air through said opening.

16. The assembly of claim 15, further comprising a heat exchanger mounted to said free surface between said free surface and said opening.

17. The assembly of claim 15, further comprising a thermoelectric module interposed between said free surface and said heat exchanger.

18. The assembly of claim 17, wherein said thermoelectric module comprises a bismuth-telluride material.

19. The assembly of claim 15, further comprising an enclosed channel around a perimeter of said opening, wherein at least a portion of said enclosed channel is disposed between said free surface and said opening.

20. The assembly of claim 19, further comprising an EMI screen disposed across said opening.

21. A method for cooling a powered semiconductor device in an assembly comprising an enclosure, a powered semiconductor device mounted in an interior of the enclosure, the device having a free surface opposing an exterior wall of the enclosure, an opening aligned opposite the free surface in the exterior wall, and a fan mounted to the assembly and disposed to move air through the opening, said method comprising the step of operating the fan to blow air from the interior of the enclosure through the opening to an exterior of the enclosure.

22. An enclosure for an electronics component, said enclosure comprising:
a plurality of walls comprised of a heat conducting material operatively coupled to enclose an interior space for a modular electronic component;
a heat exchanger conductively coupled to an exterior side of at least one of said plurality of walls;
means for conducting heat from the modular electronic component on an interior side of said at least one of said plurality of walls; and
means for convection of heat from said heat exchanger on an exterior side of said at least one of said plurality of walls.

23. The enclosure of claim 22, wherein said means for convection of heat comprises at least one blower for forcing air over an exterior surface of the heat exchanger, wherein said blower is mounted to said enclosure.

24. The enclosure of claim 22, wherein said at least one blower is connected to an electrical connection passing through said at least one of said plurality of walls.

25. The enclosure of claim 22, wherein said electronic component comprises a hard disk drive assembly.

26. The enclosure of claim 22, wherein said means for conducting heat comprises a mounting surface on an interior side of said at least one of said plurality of walls, said mounting surface configured for mating with a surface of said electronic component.

27. The enclosure of claim 22, wherein said heat exchanger comprises at least a portion of said at least one wall.
